(19) United States
(12) Patent Application Publication
(10) Pub. No.: US 2017/0162555 A1
(43) Pub. Date: Jun. 8, 2017

(54) SOLDER COMPOSITION AND SEMICONDUCTOR PACKAGE INCLUDING THE SAME

(71) Applicants: Junglae Jo, Hwaseong-si (KR); Yeo-Hoon Yoon, Yongin-si (KR); Hojeong Moon, Daejeon (KR); Taeeun Kim, Hwaseong-si (KR)

(72) Inventors: Junglae Jo, Hwaseong-si (KR); Yeo-Hoon Yoon, Yongin-si (KR); Hojeong Moon, Daejeon (KR); Taeeun Kim, Hwaseong-si (KR)

(21) Appl. No.: 15/346,089

(22) Filed: Nov. 8, 2016

(30) Foreign Application Priority Data
Dec. 8, 2015 (KR) 10-2015-0174320

(51) Int. Cl. H01L 25/18; B23K 35/26; H01L 25/065; C22C 13/00; H01L 23/498; H01L 23/00

(52) U.S. Cl. CPC H01L 25/18; H01L 23/49838; H01L 24/17; H01L 24/06; H01L 25/0657; H01L 24/81; C22C 13/00; B23K 35/262; H01L 2224/13139; H01L 2224/13147; H01L 2224/13155; H01L 2224/13111; H01L 2224/13113; H01L 2224/05147; H01L 2224/05155; H01L 2224/05144; H01L 2225/06572; H01L 2225/06517; H01L 2224/16227; H01L 2224/0401; H01L 2924/014; H01L 2924/1431; H01L 2924/1434; H01L 2225/0651; H01L 2224/48091; H01L 2224/48106; H01L 2224/48227; H01L 2225/0652

(57) ABSTRACT

Solder compositions for semiconductor fabrication are provided that include silver (Ag) of 3.0 wt. % to 4.0 wt. %, copper (Cu) of 0.75 wt. % to 1.0 wt. %, nickel (Ni) of 0.08 wt. % to 1.0 wt. %, and tin (Sn) of 94 wt. % to 96.17 wt. %, or that include bismuth (Bi) of 0.3 wt. % to 2.0 wt. % in place of a portion of the tin (Sn) in the solder composition; and, semiconductor packages are also provided that use the solder compositions for bonding one or more components of the semiconductor packages to each other.

### CROSS-REFERENCE TO RELATED APPLICATION

This U.S. non-provisional patent application claims priority under 35 U.S.C. §119 to Korean Patent Application No. 10-2015-0174320, filed on Dec. 8, 2015, in the Korean Intellectual Property Office, the disclosure of which is hereby incorporated by reference in its entirety.

### BACKGROUND

Embodiments of the inventive concepts relate to a solder composition and a semiconductor package including the same and, more particularly, to a Sn—Ag—Cu—Ni-based solder composition and a semiconductor package including the same.

As the sizes of electronic products have increasingly been reduced, small and highly-integrated semiconductor packages have increasingly been demanded in the semiconductor industry. Thus, research has been conducted on improved techniques for mounting a large number of semiconductor chips on a substrate having a limited size.

A soldering technique is a type of bonding technique using solder that may be used to mount a small electronic component (e.g., a semiconductor chip or a resistance chip) on a substrate. Bonding techniques using solder can be improved, however, to produce small, light, multi-functional and high-density electronic products.

Currently, research is being conducted on techniques capable of effectively mounting semiconductor chips having different functions on a substrate; and, related to these developments, external connection terminals of semiconductor packages are being changed from leads into solder balls.

### SUMMARY

Embodiments of the inventive concepts may provide a high-strength solder composition having excellent resistance to both mechanical impact and thermal stress.

Embodiments of the inventive concepts may also provide a semiconductor package including a connection terminal having excellent resistance (or durability) to mechanical impact and thermal stress.

In an aspect, a solder composition may include the following components: silver (Ag) of about 3.0 wt. % to about 4.0 wt. %, copper (Cu) of about 0.75 wt. % to about 1.0 wt. %, nickel (Ni) of about 0.08 wt. % to about 1.0 wt. %, and tin (Sn) of about 94 wt. % to about 96.17 wt. %.

In an aspect, a semiconductor package may include a first interconnection substrate having a top first substrate surface and a bottom first substrate surface opposite to the top first substrate surface, a first semiconductor chip disposed on the top first substrate surface and having a first chip surface facing the top first substrate surface of the first interconnection substrate and a second chip surface opposite to the first chip surface, and first connection terminals disposed between the first interconnection substrate and the first semiconductor chip, wherein the first semiconductor chip may be mounted on the first interconnection substrate through the first connection terminals by a flip-chip bonding method, wherein the first connection terminals may include a solder composition including silver (Ag) of 3.0 wt. % to 4.0 wt. %, copper (Cu) of 0.75 wt. % to 1.0 wt. %, nickel (Ni) of 0.08 wt. % to 1.0 wt. %, and tin (Sn) of 94 wt. % to 96.17 wt. %.

In an aspect, a solder composition consists essentially of silver (Ag) of 3.0 wt. % to 4.0 wt. %; copper (Cu) of 0.75 wt. % to 1.0 wt. %; nickel (Ni) of 0.08 wt. % to 1.0 wt. %; and tin (Sn) of 94 wt. % to 96.17 wt. %.

In an aspect, a method of preparing a semiconductor device comprises the steps of: providing a first interconnection substrate having a top first substrate surface with one or more first solder pads disposed thereon; providing a first semiconductor chip having a first chip surface with one or more second solder pads disposed thereon at locations such that the second solder pads align with corresponding first solder pads when the first semiconductor chip is connected with the first interconnection substrate; and, connecting the second solder pads with the corresponding first solder pads using a solder composition of the inventive concepts.

### BRIEF DESCRIPTION OF THE DRAWINGS

The patent or application file contains at least one drawing executed in color. Copies of this patent or patent application publication with color drawings will be provided by the Office upon request and payment of the necessary fee.

The inventive concepts will become more apparent in view of the attached drawings and accompanying detailed description.

FIGS. 1 and 2 are schematic cross-sectional views illustrating semiconductor packages according to some embodiments of the inventive concepts.

FIGS. 3A to 3D are scanning electron microscope (SEM) images showing an interface between solder of an experimental example 1 and an organic solderability preservative (OSP) pad and an interface between the solder of the experimental example 1 and an electroless nickel/immersion gold (ENIG) pad.

FIGS. 4A to 4D are SEM images showing an interface between solder of a comparative example 1 and an OSP pad and an interface between the solder of the comparative example 1 and an ENIG pad.

FIG. 5 is a SEM image showing a cross section of a solder ball of a printed circuit board (PCB) module using a composition of the experimental example 1 after a reflow process.

FIG. 6 is a SEM image showing a cross section of a solder ball of a PCB module using a composition of the comparative example 1 after a reflow process.

FIG. 7 is a graph showing thermal resistance and mechanical strength of a solder composition according to a bismuth concentration in the solder composition.

### DETAILED DESCRIPTION OF THE EMBODIMENTS

[Solder Composition]

A solder composition according to some embodiments of the inventive concepts may include a solder alloy including silver (Ag), copper (Cu), nickel (Ni), and tin (Sn). In detail, the solder composition may consist essentially of silver (Ag) of 3.0 wt. % to 4.0 wt. %, copper (Cu) of 0.75 wt. % to 1.0 wt. %, nickel (Ni) of 0.08 wt. % to 1.0 wt. %, and tin (Sn) of 94 wt. % to 96.17 wt. %.

It has been found that including silver (Ag) in the solder composition may increase or improve resistance to thermal stress and strength of the solder composition. A thermal characteristic, as well as the hardness and softness, of the solder composition may be changed according to a content of silver (Ag). In some embodiments, as the silver (Ag) content increases in the solder composition, the resistance to thermal stress and the strength of the solder composition may increase, but at the same time the softness of the solder composition may decrease. In addition, as the silver (Ag) content increases in the solder composition, grains having a clear grain boundary therebetween may be formed; and, as a result, segregation of Ag₃Sn may be concentrated at a center of the grain boundary. Thus, it is possible to increase resistance of the solder composition to oxidation caused by moisture absorption. On the one hand, it has been found that, if the silver (Ag) content is lower than about 3.0 wt. % in the solder composition, electrical and thermal conductivities of the solder composition may not be sufficient for the desired semiconductor applications. In addition, the softness of the solder composition may be increased by an increase in the silver (Ag) content, and thus the strength (impact resistance) of the solder composition to mechanical impact may be increased but the resistance of the solder composition to thermal stress may be rapidly decreased. On the other hand, it has also been found that, if the silver (Ag) content is higher than about 4.0 wt. % in the solder composition, the resistance of the solder composition to thermal stress may not be improved and the mechanical strength of the solder composition may be rapidly decreased. In addition, a cost of manufacturing the solder composition may be increased. Thus, the solder composition according to the inventive concepts may include silver (Ag) of 3.0 wt. % to 4.0 wt. %. In particular, the solder composition according to the inventive concepts may include silver (Ag) of 3.0 wt. % to 3.5 wt. %.

It has also been found that including copper (Cu) and nickel (Ni) in the solder composition may inhibit an inter-metallic compound (IMC) from being generated between the solder composition and a pad of a substrate or a device (or a chip) when the substrate and the device (or the chip) are bonded to each other using the solder composition. In detail, in a process of mounting the device on a substrate, the solder composition may be provided onto a pad disposed on one surface of the substrate and/or on the device (or the chip), and then may be bonded to the pad by a reflow process. Here, the pad disposed on the substrate or the device (or the chip) may be formed of gold (Au), nickel (Ni), or copper (Cu). The gold (Au), nickel (Ni), or copper (Cu) of the pad may be diffused into the solder through an interface between the pad and the solder during the reflow process, thereby forming an inter-metallic compound (IMC) such as a nickel-tin ally (e.g., Ni₃Sn₄) or a copper-tin alloy (e.g., Cu₃Sn or Cu₆Sn₅). The inter-metallic compound (IMC) may be grown along the grain boundary disposed in the solder in a direction substantially perpendicular to the interface between the pad and the solder. Thus, Kirkendall voids may be formed in the solder to reduce the hardness of the solder composition. In other words, the solder composition may have a brittle mechanical characteristic. As a result, a crack can sometimes occur from the interface between the solder and the pad by stress which is applied to the interface by a difference in coefficient of thermal expansion between the substrate and device in an external environment (e.g., rapid temperature change). However, according to some embodiments of the inventive concepts, the solder composition may include copper (Cu) and nickel (Ni) which are supersaturated at concentrations in the solder composition such that they are close to melting limit values, and thus it is possible to inhibit copper (Cu) and nickel (Ni) from being diffused from the pad into the solder composition. In some embodiments, the solder composition according to the inventive concepts may include copper (Cu) of about 0.75 wt. % to about 1.0 wt. % and nickel (Ni) of about 0.08 wt. % to about 1.0 wt. %. In particular, the solder composition may include copper (Cu) of about 0.75 wt. % to about 0.9 wt. % and nickel (Ni) of about 0.08 wt. % to about 1.0 wt. %.

It has also been found that including tin (Sn) in the solder composition may reduce a melting point of a bonding basic material and may be an element greatly affecting the cost of manufacturing the solder composition. If a content of tin (Sn) is too high or too low, a melting point of the solder composition may be increased. Thus, the quality of the solder composition may deteriorate during a soldering process. This may have a negative influence on the durability of the components of a semiconductor package. In detail, a content of tin (Sn) may be a value obtained by subtracting the contents of silver (Ag), copper (Cu), nickel (Ni), and the minor amounts of unavoidable impurities from the total content of the solder composition. In other words, the solder composition according to the inventive concepts may include tin (Sn) of 94.0 wt. % to 96.17 wt. %.

In some embodiments, the solder composition may further include a small content of bismuth (Bi). In other words, the solder composition may include a solder alloy including silver (Ag), copper (Cu), nickel (Ni), tin (Sn), and bismuth (Bi). In detail, the solder composition may include silver (Ag) of 3.0 wt. % to 4.0 wt. %, copper (Cu) of 0.75 wt. % to 1.0 wt. %, nickel (Ni) of 0.08 wt. % to 1.0 wt. %, bismuth (Bi) of 0.3 wt. % to 2.0 wt, and tin (Sn) of 93 wt. % to 95.87 wt. %.

It has been found that including bismuth (Bi) in the solder composition may inhibit an inter-metallic compound (IMC) from being generated between the solder composition and the pad of the substrate or of the device (or the chip) when the substrate and the device (or the chip) are bonded to each other using the solder composition. In addition, it has been found that including a small amount of bismuth (Bi) in the solder composition may reduce the sizes of the grains of the solder composition. The solder composition according to the inventive concepts may be a tin (Sn)-based alloy. The melting limit values of gold (Au), copper (Cu) and nickel (Ni) in relation to the solder composition in a liquid state may be reduced when the solder composition includes bismuth (Bi). Thus, it is possible to inhibit growth of the inter-metallic compound (IMC) at the interface with the solder composition. In addition, at least a portion of bismuth (Bi) may be soluble in the grain boundary of the solder composition. Thus, it is possible to inhibit the inter-metallic compound (IMC) from being grown along the grain boundary. In addition, bismuth (Bi) soluble in the grain boundary may inhibit growth of the grains of the solder composition, and thus an average size of the grains of the solder composition may be reduced. Here, a growth rate of the grain size of the solder composition may range from 0% to 15% after the reflow process. A crack corresponding to mechanical breakage may be generated along the grain boundary having the smallest energy in the solder composition, and the energy consumed in such breaking may vary according to a path of the crack. According to some embodiments of the inventive concepts, the path of the crack may be increased by a reduction in the size of the grains of the solder composition, and thus a larger amount of energy may be needed to break the solder composition. As a result, the mechanical strength of the solder composition may be increased. On one hand, if the content of bismuth (Bi) is lower than 0.3 wt. % in the solder composition, however, the improvement in the mechanical strength of the solder composition resulting from the bismuth (Bi) may be insignificant even though the content of the bismuth (Bi) is changed. In addition, the resistance of the solder composition to thermal stress may rapidly diminish. On the other hand, if the content of bismuth (Bi) is higher than 2.0 wt. % in the solder composition, the growth of the inter-metallic compound (IMC) may be inhibited but bonding reliability of the interface may be diminished since the mechanical characteristic of bismuth (Bi) is more brittle than that of tin (Sn). Thus, the solder composition according to the inventive concepts may advantageously include bismuth (Bi) in the amounts of 0.3 wt. % to 2.0 wt. %. In particular, the solder composition according to the inventive concepts may include bismuth (Bi) of 0.5 wt. % to 1.0 wt. %.

The solder composition according to some embodiments of the inventive concepts may include silver (Ag) of 3.0 wt. % or more so that the solder composition will have excellent resistance to thermal stress.

In addition, the solder composition according to some embodiments of the inventive concepts may include copper (Cu) and nickel (Ni) in amounts that are close to the melting limit values. Thus, it is possible to inhibit the inter-metallic compound (IMC) from being formed at the interface between the solder and the pads during the reflow process. As a result, the solder composition may improve the bonding reliability between the solder and the pads and may also have excellent resistance to mechanical impact.

Furthermore, the solder composition according to some embodiments of the inventive concepts may further include a small amount of bismuth (Bi) to inhibit the growth of grains of the solder composition during the reflow process. Thus, the solder composition may have fine grains. Such fine grains may increase the path of a crack that may develop in the solder composition and thereby increase the strength of the solder composition.

The solder composition according to some embodiments of the inventive concepts may have excellent resistance (or durability) to thermal stress as well as excellent resistance (or durability) to mechanical impact. Thus, semiconductor packages and electronic products using the solder composition for bonding may have excellent bonding reliability, thereby minimizing defects thereof.

[Semiconductor Package]

A semiconductor package may be manufactured using the solder composition including the alloy(s) described above. A connection terminal using the solder composition may be formed in a shape of a bar, a sphere, a paste, or a wire so as to be used in processes of manufacturing the semiconductor package and an electronic product incorporating the semiconductor package. In some embodiments, the solder composition may further include flux for preventing oxidation of the solder composition during a soldering process.

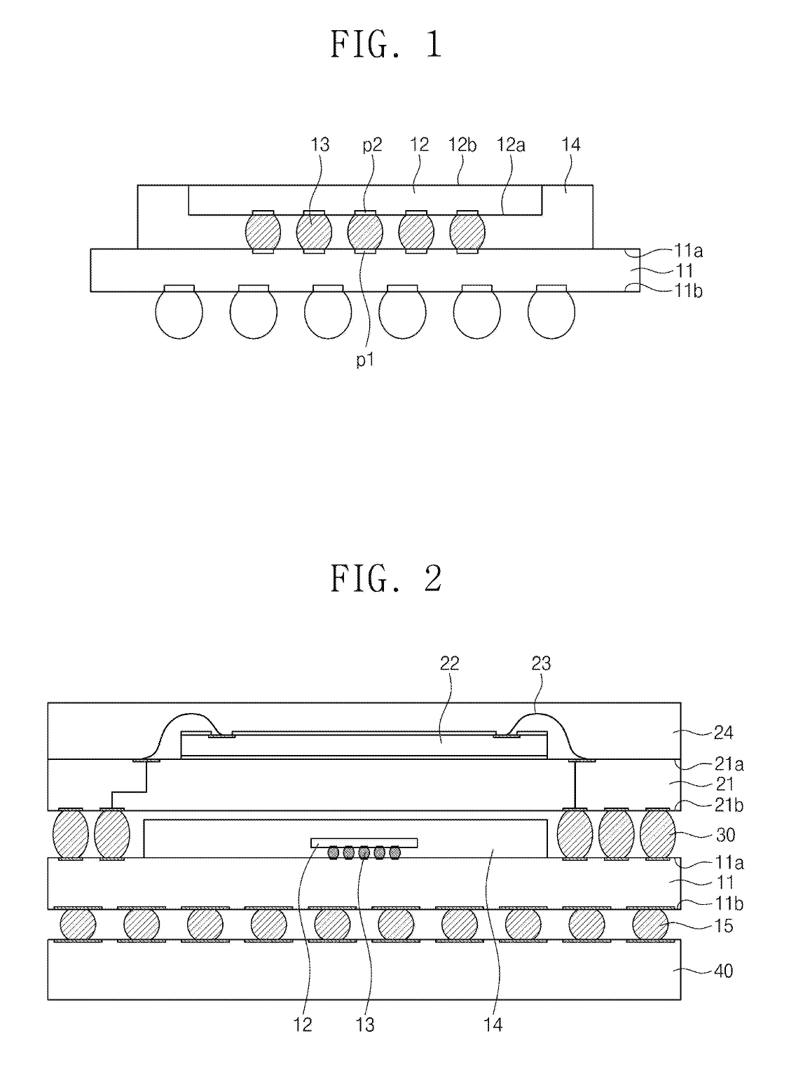

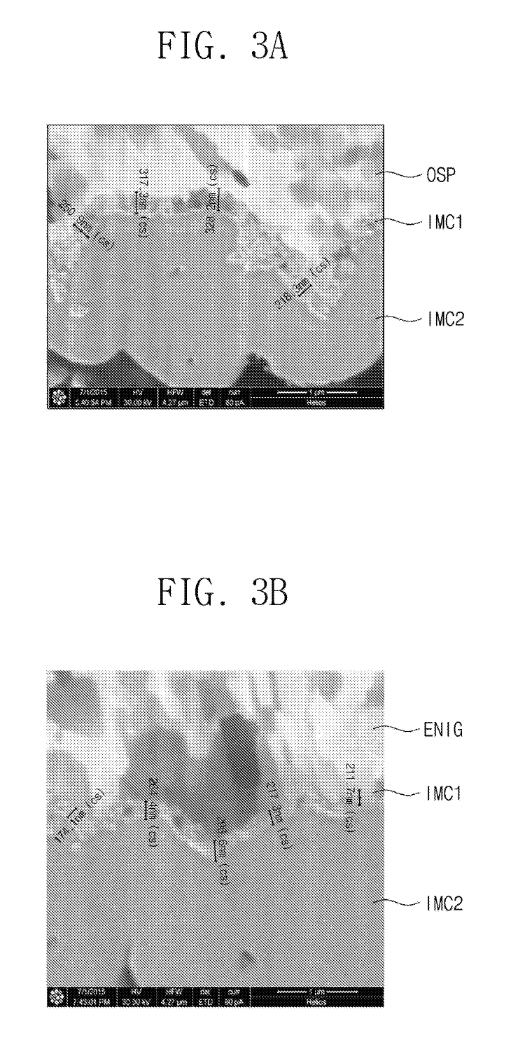

FIGS. 1 and 2 are schematic cross-sectional views illustrating semiconductor packages according to some embodiments of the inventive concepts.

Referring to FIG. 1, a first interconnection substrate 11 may be provided. The first interconnection substrate 11 may include a rigid substrate or a flexible substrate. For example, the first interconnection substrate 11 may include an epoxy-based resin or a polyethylene-based resin. The first interconnection substrate 11 may have a top first substrate surface 11a and a bottom first substrate surface 11b opposite to the top first substrate surface 11a. The first interconnection substrate 11 may also include first solder pads p1 disposed on the top first substrate surface 11a thereof. In some embodiments, the first solder pads p1 may be formed of copper (Cu), nickel (Ni), or gold (Au). The first solder pad p1 may be a first type solder pad or a second type solder pad. For example, the first type solder pad may be an electroless nickel/immersion gold (ENIG) solder pad which is formed by plating electroless nickel and immersion gold on copper (Cu). For example, the second type solder pad may be an organic solderability preservative (OSP) solder pad which is formed by applying an organic solderability preservative to copper (Cu) to prevent oxidation during a soldering process.

A first semiconductor chip 12 may be disposed on the top first substrate surface 11a of the first interconnection substrate 11. The first semiconductor chip 12 may have a first chip surface 12a facing the top first substrate surface 11a of the interconnection substrate 11 and a second chip surface 12b opposite to the first chip surface 12a. The first semiconductor chip 12 may include second solder pads p2 disposed on the first chip surface 12a thereof. In some embodiments, the second solder pads p2 may be formed of copper (Cu), nickel (Ni), or gold (Au). The second solder pad p2 may be the first type solder pad or the second type solder pad, as described above. The first semiconductor chip 12 may include a memory chip or a system large scale integrated (system LSI) semiconductor chip. A portion of the first interconnection substrate 11 and the first semiconductor chip 12 may be covered with a first molding layer 14. The first molding layer 14 may include an epoxy mold compound (EMC). As shown in FIG. 1, a region surrounding the first semiconductor chip 12, i.e., a peripheral region of the first interconnection substrate 11, may not be covered with the first molding layer 14 but may be exposed at this stage of a manufacturing process. A sidewall of the first semiconductor chip 12 may be covered by the first molding layer 14, but the second surface 12b of the first semiconductor chip 12 may be exposed.

First connection terminals 13 may be disposed between the first interconnection substrate 11 and the first semiconductor chip 12. In more detail, the first connection terminals 13 may b e disposed between the first solder pads p1 of the first interconnection substrate 11 and the second solder pads p2 of the first semiconductor chip 12, respectively. The solder composition, which may be melted by a reflow process in an infra-red (IR) oven, may be adhered to the first solder pad p1 and the second solder pad p2, thereby foiming the first connection terminals 13. Thus, the first semiconductor chip 12 may be mounted on the first interconnection substrate 11. The first connection terminals 13 may electrically connect the first semiconductor chip 12 to the first interconnection substrate 11. In other words, the first semiconductor chip 12 may be mounted on the first interconnection substrate 11 through the first connection terminals 13 by a flip-chip bonding method. The first connection terminals 13 may include the solder composition as described above. In other words, the first connection terminals 13 may include the alloy including silver (Ag) of 3.0 wt. % to 4.0 wt. %, copper (Cu) of 0.75 wt. % to 1.0 wt. %, nickel (Ni) of 0.08 wt. % to 1.0 wt. %, and tin (Sn) of 94 wt. % to 96.17 wt. %. Alternatively, the first connection terminals 13 may include the alloy including silver (Ag) of 3.0 wt. % to 4.0 wt. %, copper (Cu) of 0.75 wt. % to 1.0 wt. %, nickel (Ni) of 0.08 wt. % to 1.0 wt. %, bismuth (Bi) of 0.3 wt. % to 2.0 wt, and tin (Sn) of 93 wt. % to 95.87 wt. %. As a result, the first connection terminals 13 may include silver (Ag) of 3.0 wt. % or more, and thus the first connection terminals 13 may have excellent resistance to terminal stress. In addition, the first connection terminals 13 may include copper (Cu) of 0.75 wt. % or more and nickel (Ni) of 0.08 wt. % or more, and thus the first connection terminals 13 may have excellent resistance to mechanical impact. In particular, the first connection terminals 13 may have excellent bonding characteristics and strength at the interfaces between the first connection terminals 13 and the solder pads and p2. In some embodiments, the first connection terminals 13 may include bismuth (Bi) of 0.3 wt. % or more, thus the first connection terminals 13 may also have excellent resistance to mechanical impact. The composition ratio of the first connection terminals 13 may be the same as that of the solder composition as described above, and thus the descriptions thereof will be omitted.

A semiconductor package according to some embodiments of the inventive concepts may be a stack-type semiconductor package.

Referring to FIG. 2, a second interconnection substrate 21 may be disposed on the first semiconductor chip 12. The second interconnection substrate 21 may include a rigid substrate or a flexible substrate. For example, the second interconnection substrate 21 may include an epoxy-based resin or a polyethylene-based resin. The second interconnection substrate 21 may have a top second substrate surface 21 a and a bottom second substrate surface 21b opposite to the top second substrate surface 21a.

A second semiconductor chip 22 may be disposed on the top second substrate surface 21a of the second interconnection substrate 21. In some embodiments, the first semiconductor chip 12 may be a logic chip, and the second semiconductor chip 22 may be a memory chip. The second semiconductor chip 22 may be mounted on the second interconnection substrate 21 through wires 23 by a wire bonding method. Alternatively, the second semiconductor chip 22 may be mounted on the second interconnection substrate 21 by a flip-chip bonding method. The second interconnection substrate 21 and the second semiconductor chip 22 may be covered with a second molding layer 24. The second molding layer 24 may include an epoxy mold compound (EMC).

Second connection terminals 30 may be disposed between the first interconnection substrate 11 and the second interconnection substrate 21. In detail, the second connection terminals 30 may be disposed between the top first substrate surface 11a of the first interconnection substrate 11 and the bottom second substrate surface 21b of the second interconnection substrate 21 and may be disposed around the first semiconductor chip 12, i.e., on the peripheral region of the first interconnection substrate 11. The second connection terminals 30 may be formed of the solder composition melted by a reflow process in an IR oven. The first interconnection substrate 11 may be electrically connected to the second interconnection substrate 21 through the second connection terminals 30. In other words, the second interconnection substrate 21 may be mounted on the first interconnection substrate 11. The second connection terminals 30 may include the solder composition as described above. In other words, the second connection terminals 30 may include the alloy including silver (Ag) of 3.0 wt. % to 4.0 wt. %, copper (Cu) of 0.75 wt. % to 1.0 wt. %, nickel (Ni) of 0.08 wt. % to 1.0 wt. %, and tin (Sn) of 94 wt. % to 96.17 wt. %. Alternatively, the second connection terminals 30 may include the alloy including silver (Ag) of 3.0 wt. % to 4.0 wt. %, copper (Cu) of 0.75 wt. % to 1.0 wt. %, nickel (Ni) of 0.08 wt. % to 1.0 wt. %, bismuth (Bi) of 0.3 wt. % to 1.0 wt, and tin (Sn) of 93 wt. % to 95.87 wt. %.

In some embodiments, as shown in FIG. 2, the semiconductor package may further include a main substrate 40 disposed under the first interconnection substrate 11. As illustrated in FIG. 2, the first interconnection substrate 11 may include external connection terminals 15 disposed on the bottom first substrate surface 11b thereof. The first interconnection substrate 11 may be electrically connected to the main substrate 40 through the external connection terminals 15. The main substrate 40 may be electrically connected to the first semiconductor chip 12 and the second semiconductor chip 22 through the external connection terminals 15. The external connection teiminals 15 may be fainted of the solder composition melted by a reflow process in an IR oven. The first interconnection substrate 11 may be mounted on the main substrate 40 through the external connection terminals 15. The external connection terminals 15 may include the solder composition described above. In other words, the external connection terminals 15 may include the alloy including silver (Ag) of 3.0 wt. % to 4.0 wt. %, copper (Cu) of 0.75 wt. % to 1.0 wt. %, nickel (Ni) of 0.08 wt. % to 1.0 wt. %, and tin (Sn) of 94 wt. % to 96.17 wt. %. Alternatively, the external connection terminals 15 may include the alloy including silver (Ag) of 3.0 wt. % to 4.0 wt. %, copper (Cu) of 0.75 wt. % to 1.0 wt. %, nickel (Ni) of 0.08 wt. % to 1.0 wt. %, bismuth (Bi) of 0.3 wt. % to 1.0 wt, and tin (Sn) of 93 wt. % to 95.87 wt. %.

Embodiments of the inventive concepts may applied to manufacture a ball grid array (BGA) semiconductor package and a solid state disk (SSD) which use solder balls as connection terminals. For example, embodiments of the inventive concepts may be applied to manufacture various stack-type semiconductor packages and multi-memory devices. As a result, the stack-type semiconductor package, the SSD, and the electronic device which are manufactured using the solder composition according to the inventive concepts may have excellent resistances to mechanical impact and thermal stress, and thus they may have excellent bonding reliability.

### EXPERIMENTAL EXAMPLE

Hereinafter, characteristics and features of embodiments of the inventive concepts will be described in more detail with reference to experimental examples using the solder composition according to the inventive concepts and also comparative examples not using the solder composition for evaluating the experimental examples. However, embodiments of the inventive concepts are not limited to the experimental examples herein presented. SAC302 (comparative example 1) and SAC2307 (comparative example 2), which were used commonly, were used here as the comparative examples for comparison purposes.

### Experimental Example 1

A solder ball was formed of an alloy including silver (Ag) of 3.0 wt. %, copper (Cu) of 0.8 wt. %, nickel (Ni) of 0.08 wt. %, bismuth (Bi) of 1.0 wt. %, and tin (Sn) corresponding to the rest of the experimental alloy composition.

### Experimental Example2

A solder ball was formed of an alloy including silver (Ag) of 3.0 wt. %, copper (Cu) of 0.75 wt. %, nickel (Ni) of 0.08 wt. %, bismuth (Bi) of 1.0 wt. %, and tin (Sn) corresponding to the rest of the experimental alloy composition.

### Experimental Example 3

A solder ball was formed of an alloy including silver (Ag) of 3.0 wt. %, copper (Cu) of 0.8 wt. %, nickel (Ni) of 0.08 wt. %, and tin (Sn) corresponding to the rest of the experimental alloy composition.

### Comparative Example 1

A solder ball was formed of an alloy including silver (Ag) of 3.0 wt. %, copper (Cu) of 0.2 wt. %, and tin (Sn) corresponding to the rest of the comparative alloy composition.

### Comparative Example 2

A solder ball was farmed of an alloy including silver (Ag) of 2.3 wt. %, copper (Cu) of 0.7 wt. %, nickel (Ni) of 0.08 wt. %, and tin (Sn) corresponding to the rest of the comparative alloy composition.

Semiconductor packages were manufactured using the solder balls according to the experimental examples 1 and 2 and the comparative examples 1 and 2, and a temperature cycle test was performed on each of the manufactured semiconductor packages. The temperature cycle test was performed 700 times in a temperature range of −40 degrees Celsius to +85 degrees Celsius to check breakage of an interface bonding layer between a solder ball and an associated solder pad. Here, the solder pad was the ENIG solder pad or the OSP solder pad, as described above. The following table 1 shows an occurrence rate of a defect according to the composition ratio of the solder ball, which was obtained by the temperature cycle test.

TABLE 1

| | | Solder pad | |
|---|---|---|---|
| | Composition ratio of solder | ENIG | OSP |
| Experimental | Sn, Ag of 3.0 wt %, Cu of 0.8 wt %, | 14% | 2% |
| example 1 | Ni of 0.08 wt %, Bi of 1.0 wt % | | |
| Experimental | Sn, Ag of 3.0 wt %, Cu of 0.75 | 40% | 30% |
| example 2 | wt %, Ni of 0.08 wt %, Bi of 1.0 wt % | | |
| Comparative | Sn, Ag of 3.0 wt %, Cu of 0.2 wt % | 75% | 48% |
| example 1 | | | |
| Comparative | Sn, Ag of 2.3 wt %, Cu of 0.7 wt %, | 47% | 44% |
| example 2 | Ni of 0.08 wt % | | |

Referring to Table 1, the occurrence rate of the defect was about 2% or about 14%, depending on the kind of solder pad used, in the case of the solder composition of experimental example 1. The occurrence rate of the defect was about 30% or about 40%, depending on the kind of solder pad used, in the case of the solder composition of experimental example 2. The occurrence rate of the defect was about 48% or about 75%, depending on the kind of solder pad used, in the case of the solder composition of comparative example 1. The occurrence rate of the defect was about 44% or about 47%, depending on the kind of solder pad used, in the case of the solder composition of comparative example 2. It may be recognized that the resistances to thermal stress of the experimental examples manufactured according to the inventive concepts are improved as compared with the resistances to theimal stress of the comparative examples. In other words, the solder compositions according to some embodiments of the inventive concepts may inhibit the interface bonding layer between a solder ball and an associated solder pad from being broken by temperature variation.

PCB modules on which semiconductor packages were mounted were manufactured using solder balls according to the experimental examples 1, 2 and 3 and also according to the comparative examples 1 and 2, and then a “drop-reliability” test was performed on each of the PCB modules. The drop-reliability test is a reliability test that checks impact applied to the semiconductor package when the PCB module drops face-down on a rigid base from a predetermined height by a drop-reliability test apparatus. In these tests, each of the PCB modules was repeatedly dropped until an initial defect (i.e., a crack of the interface bonding layer between a solder ball and an associated solder pad) occurred, and impact load applied to the PCB module was set to 1500G. The following Table 2 shows the average of the numbers of times a PCB test module was dropped before the initial defect occurred.

TABLE 2

| | | Drop reliability |
|---|---|---|
| | | test (the number |
| | Composition ratio of solder | of times) |
| Experimental | Sn, Ag of 3.0 wt %, Cu of 0.8 wt %, | 81 |
| example 1 | Ni of 0.08 wt %, Bi of 1.0 wt % | |
| Experimental | Sn, Ag of 3.0 wt %, Cu of 0.75 | 74 |
| example 2 | wt %, Ni of 0.08 wt %, Bi of 1.0 wt % | |
| Experimental | Sn, Ag of 3.0 wt %, Cu of 0.8 wt %, | 106 |
| example 3 | Ni of 0.08 wt % | |
| Comparative | Sn, Ag of 3.0 wt %, Cu of 0.2 wt % | 4 |
| example1 | | |
| Comparative | Sn, Ag of 2.3 wt %, Cu of 0.7 wt %, | 134 |
| example 2 | Ni of 0.08 wt % | |

Referring to Table 2, the drop reliabilities of the experimental examples 1 to 3 are lower than that of comparative example 2, but they are much higher than that of comparative example 1. In other words, it may be recognized that the solder composition according to the inventive concepts has excellent mechanical stability and excellent bonding reliability.

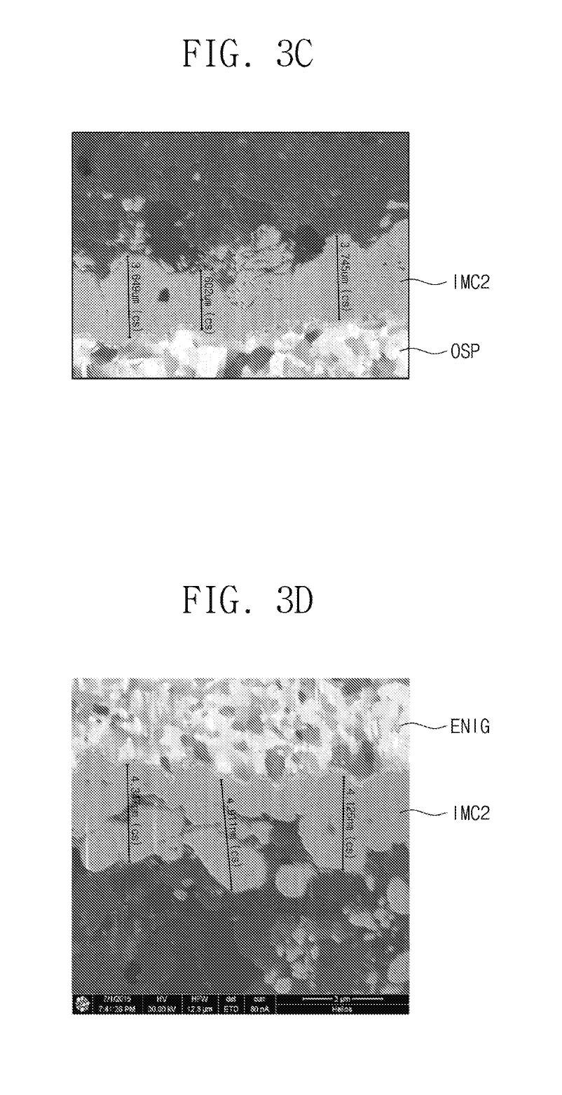

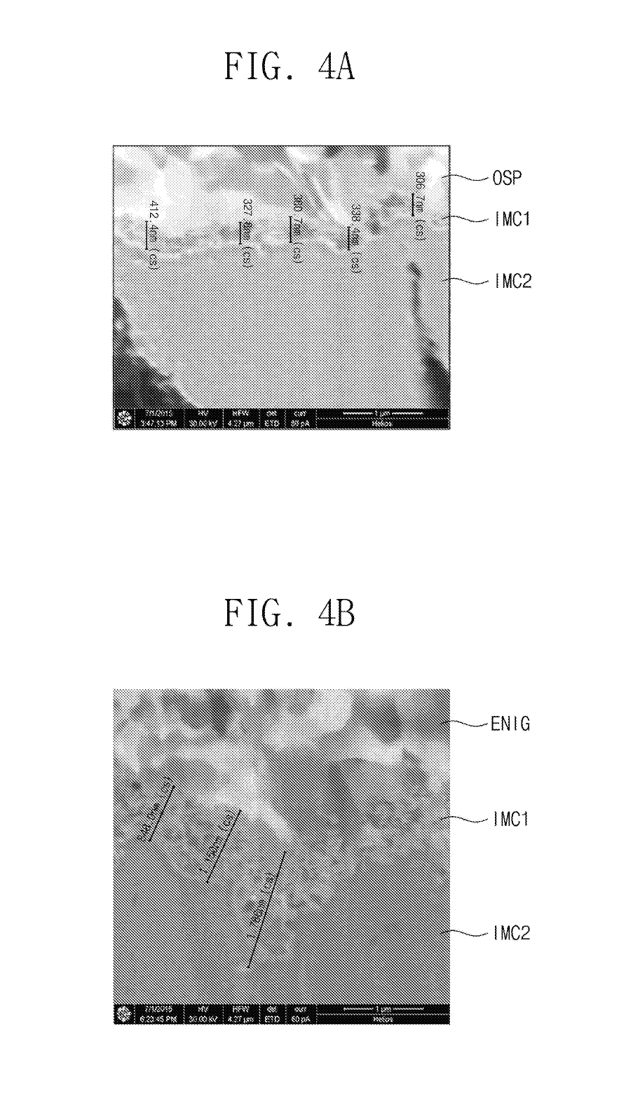

PCB modules on which semiconductor packages were mounted were manufactured using solder balls according to experimental example 1 and comparative example 1, and then inter metallic compounds (IMC) between the solder pads and the associated solder balls of the PCB modules were compared with each other and were analyzed. FIGS. 3A to 3D are scanning electron microscope (SEM) images showing an interface between solder of an experimental example 1 and an organic solderability preservative (OSP) pad (FIGS. 3A and 3C) and an interface between the solder of the experimental example 1 and an electroless nickel/immersion gold (ENIG) pad (FIGS. 3B and 3D). Referring to FIGS. 3A to 3D, in the experimental example 1, a grown thickness of Cu₃Sn (IMC1) ranges from 150nm to 350nm depending on the kind of pad, and a grown thickness of Cu₆Sn₅(IMC2) ranges from 2.5μm to 4μm depending on the kind of pad. FIGS. 4A to 4D are SEM images showing an interface between the solder of comparative example 1 and an OSP pad (FIGS. 4A and 4C) and an interface between the solder of comparative example 1 and an ENIG pad (FIGS. 4B and 4D). Referring to FIGS. 4A to 4D, in the comparative example 1, a grown thickness of

Cu₃Sn (IMC1) ranges from 300nm to 1.8μm depending on the kind of the pad, and a grown thickness of Cu₆Sn₅(IMC2) ranges from 3μm to 9μm depending on the kind of the pad. It is recognized that the Cu₃Sn and Cu₃Sn₅thicknesses formed between a solder pad and an associated solder ball in the package using the solder composition of experimental example 1 are thinner than the Cu₃Sn and Cu₆Sn₅thicknesses formed between a solder pad and an associated solder ball in the package using the solder composition of comparative example 1. In other words, the solder composition according to the inventive concepts reduces the growth of the inter-metallic compounds (IMC) between a solder ball and an associated solder pad.

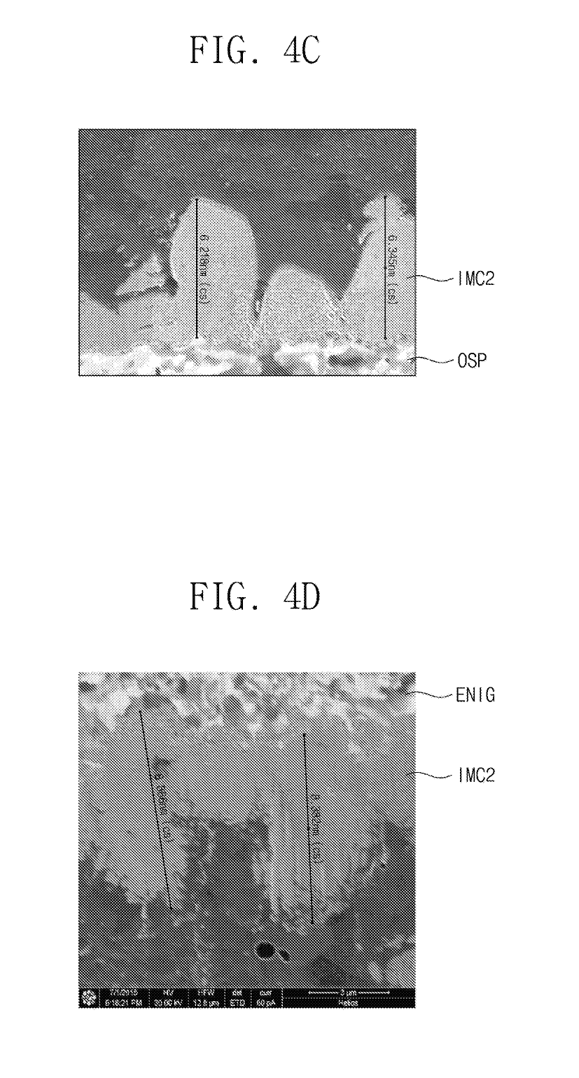

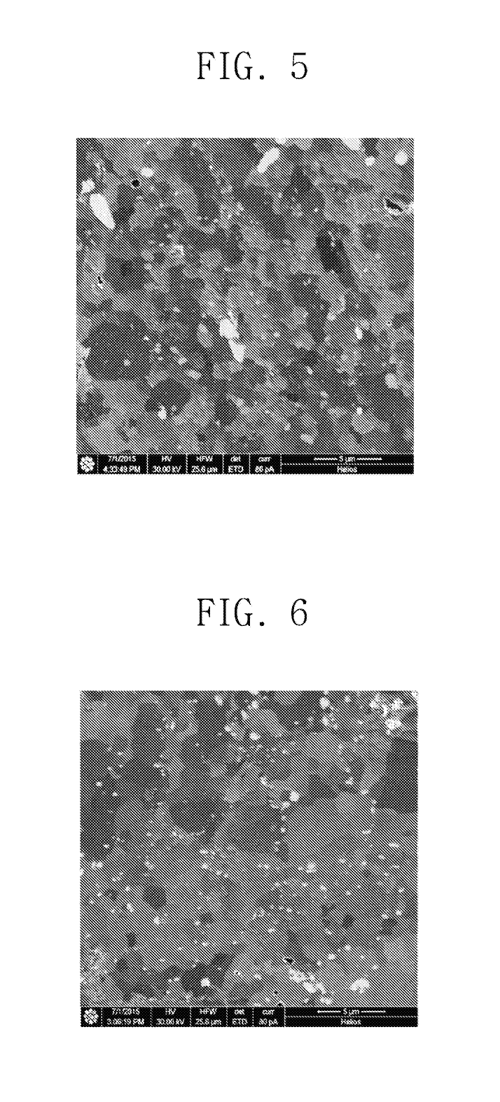

PCB modules on which semiconductor packages were mounted were manufactured using the solder balls according to experimental example 1 and comparative example 1, and then sizes of grains in the solder balls were compared with each other. FIG. 5 is a SEM image showing a cross section of a solder ball of a PCB module using a solder composition of experimental example 1 after a reflow process. FIG. 6 is a SEM image showing a cross section of a solder ball of a PCB module using a solder composition of comparative example 1 after a reflow process. Referring to FIGS. 5 and 6, after the reflow process, the sizes of the grains in the solder ball of experimental example 1 are relatively smaller than those of the grains in the solder ball of comparative example 1.

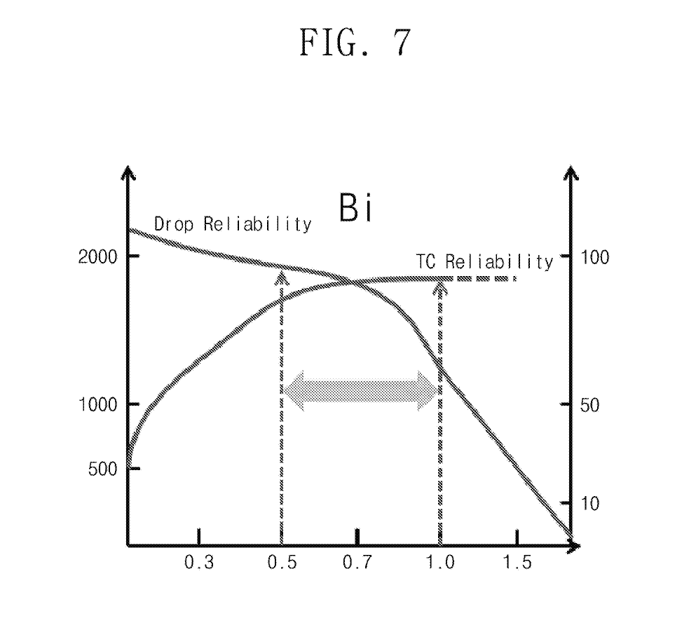

Various concentrations of bismuth (Bi) were added to the solder composition of experimental example 3 as described above to form solder balls. PCB modules having semiconductor packages were manufactured using these solder balls having different concentrations of bismuth (Bi), and then a temperature cycle test and a drop-reliability test were performed on the PCB modules. FIG. 7 is a graph showing thermal resistance and mechanical strength according to a bismuth (Bi) concentration in a modified experimental example 3 solder composition. In the present experiment, conditions of the temperature cycle test and the drop-reliability test were the same as those of the experiments described above. Referring to FIG. 7, thermal durability (TC reliability) of the solder composition increases in proportion to the concentration of bismuth (Bi) at least up to a point, and then becomes substantially saturated as the concentration of bismuth (Bi) increases above about 0.5 wt. %. In addition, the drop-reliability of the solder composition rapidly decreases as the concentration of bismuth (Bi) increases above about 0.8 wt. %. In other words, it is recognized that the combination of thermal durability (TC reliability) and mechanical characteristics of the solder composition can be improved together (or optimized) when the concentration of bismuth (Bi) ranges from 0.5 wt. % to 1.0 wt. %.

The solder composition according to some embodiments of the inventive concepts may have excellent resistance (or durability) to thermal stress as well as excellent resistance (or durability) to mechanical impact. Thus, semiconductor packages and electronic products using the solder composition for bonding in semiconductor applications may have excellent bonding reliability, thereby minimizing defects thereof.

While the inventive concepts have been described with reference to exemplary embodiments, it will be apparent to those skilled in the art that various changes and modifications may be made without departing from the spirit and scope of the inventive concepts. Therefore, it should be understood that the above embodiments are not limiting, but merely illustrative. Thus, the scope of the inventive concepts should be determined by the broadest permissible interpretation of the following claims and their equivalents, and should not be restricted or limited by the foregoing description.

1. A solder composition comprising:
silver (Ag) of 3.0 wt. % to 4.0 wt. %;
copper (Cu) of 0.75 wt. % to 1.0 wt. %;
nickel (Ni) of 0.08 wt. % to 1.0 wt. %; and
tin (Sn) of 94 wt. % to 96.17 wt. %.

2. The solder composition of claim 1, wherein a content of silver (Ag) in the solder composition ranges from 3.0 wt. % to 3.5 wt. %.

3. The solder composition of claim 1, wherein a content of copper (Cu) in the solder composition ranges from 0.75 wt. % to 0.9 wt. %.

4. The solder composition of claim 1, wherein a content of nickel (Ni) in the solder composition ranges from 0.08 wt. % to 0.5 wt. %.

5. The solder composition of claim 1, further comprising:
bismuth (Bi) of 0.3 wt. % to 2.0 wt. %, which is substituted for a portion of the tin (Sn) in the solder composition.

6. The solder composition of claim 5, wherein a content of bismuth (Bi) in the solder composition ranges from 0.5 wt. % to 1.0 wt. %.

7. The solder composition of claim 5, wherein at least a portion of the bismuth (Bi) in the solder composition is soluble in a grain boundary between grains of the solder composition.

8. The solder composition of claim 7, wherein a growth rate of a grain size of the solder composition after a reflow process ranges from 0% to 15% resulting in relatively smaller solder composition grain sizes in comparison with a comparable solder composition that does not include nickel (Ni) or bismuth (Bi).

9. A semiconductor package comprising:
a first interconnection substrate having a top first substrate surface and a bottom first substrate surface opposite to the top first substrate surface;
a first semiconductor chip disposed on the top first substrate surface, the first semiconductor chip having a first chip surface facing the top first substrate surface and a second chip surface opposite to the first chip surface; and
first connection terminals disposed between the first interconnection substrate and the first semiconductor chip,
wherein the first semiconductor chip is mounted on the first interconnection substrate through the first connection terminals by a flip-chip bonding method, and
wherein the first connection terminals include a solder composition consisting essentially of about 3.0 wt. % to about 4.0 wt. % silver (Ag), about 0.75 wt. % to about 1.0 wt. % copper (Cu), about 0.08 wt. % to about 1.0 wt. % nickel (Ni), and about 94 wt. % to about 96.17 wt. % tin (Sn).

10. The semiconductor package of claim 9, wherein the first connection terminals further include bismuth of 0.3 wt. % to 2.0 wt. %, which is substituted for a portion of the tin (Sn) in the solder composition.

11. The semiconductor package of claim 10, wherein: the first interconnection substrate comprises first solder pads disposed on the top first substrate surface,
the first semiconductor chip comprises second solder pads disposed on the first chip surface, and
the first connection terminals are disposed between the first solder pads and the second solder pads.

12. The semiconductor package of claim 11, wherein the first solder pads and the second solder pads include copper (Cu), nickel (Ni), or gold (Au).

13. The semiconductor package of claim 9, further comprising:
a second interconnection substrate disposed on the first semiconductor chip;
a second semiconductor chip mounted on the second interconnection substrate;
and
second connection terminals disposed between the first interconnection substrate and the second interconnection substrate and disposed around the first semiconductor chip,
wherein the first interconnection substrate is electrically connected to the second interconnection substrate through the second connection terminals, and
wherein the second connection terminals include the same solder composition as the first connection terminals.

14. The semiconductor package of claim 13, wherein the first semiconductor chip is a logic chip, and
wherein the second semiconductor chip is a memory chip that is mounted on the second interconnection substrate by a flip-chip bonding method or a wire bonding method.

15. The semiconductor package of claim 9, further comprising:
a main substrate disposed under the first interconnection substrate; and
external connection terminals disposed between the main substrate and the first interconnection substrate,
wherein the main substrate is electrically connected to the first interconnection substrate through the external connection terminals provided on the bottom first substrate surface, and wherein the external connection terminals include the same solder composition used for the first connection terminals.

16. A solder composition consisting essentially of:
silver (Ag) of about 3.0 wt. % to 4.0 wt. %;
copper (Cu) of about 0.75 wt. % to 1.0 wt. %;
nickel (Ni) of about 0.08 wt. % to 1.0 wt. %; and
tin (Sn) of about 94 wt. % to 96.17 wt. %.

17. The solder composition of claim 16 additionally including about 0.3 wt. % to 2.0 wt. % of bismuth (Bi).

18. The semiconductor package of claim 13, further comprising:
a main substrate disposed under the first interconnection substrate; and
external connection terminals disposed between the main substrate and the first interconnection substrate,
wherein the main substrate is electrically connected to the first interconnection substrate through the external connection terminals provided on the bottom first substrate surface, and
wherein the external connection terminals include the same solder composition as the first connection terminals.

19. A method of preparing a semiconductor device comprising the steps of:
providing a first interconnection substrate having a top first substrate surface with one or more first solder pads disposed thereon;
providing a first semiconductor chip having a first chip surface with one or more second solder pads disposed thereon at locations such that the second solder pads align with corresponding first solder pads when the first semiconductor chip is connected with the first interconnection substrate; and,
connecting the second solder pads with the corresponding first solder pads using the solder composition of claim 16.

20. The method of claim 19 wherein the first solder pads and the second solder pads comprise copper (Cu), nickel (Ni) and/or gold (Au).
